(19) United States
(12) Patent Application Publication
(10) Pub. No.: US 2006/0138470 A1
(43) Pub. Date: Jun. 29, 2006

(54) CMOS image sensor and method for fabricating the same

(76) Inventor: Chang Hun Han, Icheon-city (KR)

Correspondence Address: MCKENNA LONG & ALDRIDGE LLP, 1900 K STREET, NW, WASHINGTON, DC, 20006, US

(21) Appl. No.: 11/318,439

(22) Filed: Dec. 28, 2005

(30) Foreign Application Priority Data
Dec. 29, 2004 (KR) 10-2004-0114660

(51) Int. Cl. H01L 27/148

(52) U.S. Cl. 257/233

(57) ABSTRACT

A CMOS image sensor and a method for fabricating the same are disclosed, in which a dark current is prevented from being generated between a device isolation film and a photodiode region to improve characteristics of the image sensor.

### CROSS REFERENCE TO RELATED APPLICATION

This application claims the benefit of the Korean Patent Application No. P2004-114660, filed on Dec. 29, 2004, which is hereby incorporated by reference as if fully set forth herein.

### BACKGROUND OF THE INVENTION

1. Field of the Invention

The present invention relates to a complementary metal-oxide semiconductor (CMOS) image sensor and a method for fabricating the same, and more particularly, to a CMOS image sensor and a method for fabricating the same in which a dark current is prevented from occurring, thereby improving characteristics of the image sensor.

2. Discussion of the Related Art

Generally, an image sensor is a semiconductor device that converts optical images to electrical signals. Image sensors include charge coupled devices (CCD) and CMOS image sensors.

A CCD includes a plurality of photodiodes PD arranged in a matrix arrangement to convert optical signals to electrical signals, a plurality of vertical charge coupled devices (VCCDs) formed between the photodiodes in a vertical direction to transfer charges generated by the respective photodiodes in a vertical direction, a plurality of horizontal charge coupled devices (HCCDs) transferring the charges transferred by the VCCDs in a horizontal direction, and a sensing amplifier sensing the charges transferred in a horizontal direction to output electrical signals.

CCDs have drawbacks in their fabricating process because of a complicated driving mode, high power consumption, and multistage photolithographic processes.

Additionally, it is difficult to integrate in a CCD chip a control circuit, a signal processing circuit, and an analog-to-digital converter. Therefore, it is not possible to use a CCD and obtain a slim size product.

Recently, to overcome the drawbacks of the CCD, focus has shifted to CMOS image sensors as the next generation image sensor.

The CMOS image sensor employs a switching mode that sequentially detects outputs of unit pixels using MOS transistors by forming the MOS transistors corresponding to the number of the unit pixels on a semiconductor substrate using CMOS technology with a control circuit and a signal processing circuit used as peripheral circuits.

The CMOS image sensor sequentially detects electrical signals of each unit pixel using a switching mode to display images by forming photodiodes and MOS transistors in unit pixels.

The CMOS image sensor has a low power consumption and a simple fabricating process thanks to a relatively small number of photolithographic process steps necessary in the CMOS manufacturing technology.

Further, since the CMOS image sensor allows for a control circuit, a signal processing circuit and an analog-to-digital converter to be integrated in its chip, it can be used to manufacture slim sized product.

Because of its advantages, CMOS image sensors are widely used in various fields such as manufacturing of digital still camera and digital video camera.

The CMOS image sensor may be divided into a 3T type, a 4T type, and 5T type depending on the number of transistors. The 3T type CMOS image sensor is comprised of a photodiode and three transistors while the 4T type CMOS image sensor is comprised of a photodiode and four transistors. A layout of a unit pixel of the 3T type CMOS image sensor is described below.

FIG. 1 is a layout illustrating a unit pixel of a typical 3T type CMOS image sensor.

As shown in FIG. 1, an active region 10 is defined, so that a photodiode 20 is formed in a wide portion of the active region 10 and gate electrodes 120, 130, and 140 of three transistors overlapped with one another are formed on the remaining portion of the active region 10.

A reset transistor Rx is formed by the gate electrode 120, a drive transistor Dx is formed by the gate electrode 130, and a selection transistor Sx is formed by the gate electrode 140.

Source and drain regions for each transistor are formed by implanting impurity ions into the active region 10 of each transistor except portions below the gate electrodes 120, 130 and 140.

A power voltage Vdd is applied to the source and drain regions between the reset transistor Rx and the drive transistor Dx, and the source and drain regions at one side of the selection transistor Sx are connected to a reading circuit (not shown).

Although not shown, each of the gate electrodes 120, 130 and 140 are connected to a signal line. Each signal line is provided with a pad at one end to be connected to an external driving circuit.

A related art CMOS image sensor is also shown in FIG. 2.

FIG. 2 is a sectional view taken along line II-II of FIG. 1, illustrating a photodiode and a transfer transistor of a typical CMOS image sensor.

As shown in FIG. 2, a p⁻ type epitaxial layer 101 is formed on a p⁺⁺ type semiconductor substrate 100 defined by a device isolation region and the active region. A device isolation film 103 is formed on the device isolation region of the semiconductor substrate 100.

A gate 123 is formed on a portion of the epitaxial layer 101 for a transfer transistor 120 by interposing a gate insulating film 121. An insulating spacer 125 is formed at both sides of the gate 123.

An n⁻ type diffusion region 131 and a P^{o} type diffusion region 132 are formed in the photodiode region PD of the epitaxial layer 101.

The P^{o} type diffusion region 132 is formed on the n⁻ type diffusion region 131. The source and drain regions S/D are formed as a heavily doped n type diffusion region (n⁺) and a lightly doped n type diffusion region (n⁻).

The aforementioned typical CMOS image sensor suffers from increased dark current which deteriorates the performance of the device and its storage capacity.

Dark current is generated by electrons moving from the photodiode region to another region when light does not enter the photodiode region. The dark current is generally caused by various defects or dangling bond generated near the surface, at the boundary portion between the device isolation film and the P^{o} type diffusion region, at the boundary portion between the device isolation film and the n⁻ type diffusion region, at the boundary portion between the P^{o} type diffusion region and the n⁻ type diffusion region, in the P^{o} type diffusion region, and in the n⁻ type diffusion region. The dark current may cause serious problems in the performance of the CMOS image sensor under low illumination conditions and storage capability of charges are deteriorated.

To resolve this problem, in the related art CMOS image sensor the P^{o} type diffusion region is formed on the surface of the photodiode region so as to reduce the dark current particularly generated in the portion adjacent to the surface.

However, the related art CMOS image sensor is greatly affected by the dark current generated at the boundary portion between the device isolation film 13 and the P^{o} type diffusion region, and at the boundary portion between the device isolation film 13 and the n⁻ type diffusion region.

As shown in FIG. 2, a photoresist pattern (not shown) is formed on the semiconductor substrate 100 as an ion implantation mask layer to form the n⁻ type diffusion region 131 and the P^{o} type diffusion region 132. During this process, the whole active region for the photodiode region PD is exposed by an opening in the photoresist pattern. When impurity ions for the n⁻ type diffusion region 131 and the P^{o} type diffusion region 132 are implanted into the active region of the photodiode region PD, they are also implanted into the boundary portion between the active region and the device isolation film 103.

The ion implantation damages the boundary portion between the device isolation film 103 and the n⁻ type diffusion region, and the boundary portion between the device isolation film 103 and the P^{o} type diffusion region, and causes defects. The defects cause electron-hole carriers and recombination of the electrons. As a result, a leakage current of the photodiode region is increased and the dark current of the CMOS image sensor is also increased.

As described above, the related art CMOS image sensor has a structure in which the impurity ions are implanted into the boundary portion between the device isolation film and the active region of the photodiode during ion implantation of the impurity ions for the formation of the diffusion regions of the photodiode region. Accordingly, in the related art CMOS image sensor, it is difficult to prevent an increase in the dark current generated in the boundary portion between the device isolation film and the active region for the photodiode region. This limits improvement of characteristics relating to dark current.

### SUMMARY OF THE INVENTION

Accordingly, the present invention is directed to a CMOS image sensor and a method for fabricating the same that substantially obviates one or more problems due to limitations and disadvantages of the related art.

One advantage of the present invention is that it can provide a CMOS image sensor and a method for fabricating the same, in which a P⁺ type epitaxial layer is formed in the periphery of a device isolation film to induce recombination of electrons generated in a boundary of the device isolation film, thereby improving characteristics of the image sensor.

Additional examples of advantages and features of the present invention will be set forth in part in the description which follows, and in part will be apparent from the description or by practice of the invention.

To achieve these and other advantages and in accordance with an embodiment of the invention, as embodied and broadly described herein, a CMOS image sensor according to the present invention includes a first conductivity type semiconductor substrate defined by an active region and a device isolation region, a device isolation film formed in the device isolation region, a second conductivity type lightly doped diffusion region formed in the active region, and a first conductivity type heavily doped epitaxial layer formed in the periphery of the device isolation film including a boundary portion between the device isolation film and the second conductivity type lightly doped diffusion region.

In another aspect of the present invention, a method for fabricating a CMOS image sensor includes forming a trench in a device isolation region of a first conductivity type semiconductor substrate defined by an active region and the device isolation region, forming a first conductivity type heavily doped epitaxial layer on a surface of the trench, forming a device isolation film in the trench, and forming a second conductivity type diffusion region in the active region of the semiconductor substrate to have a constant interval from the device isolation film by the first conductivity type heavily doped epitaxial layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention.

In the drawings:

FIG. 1 is a layout illustrating a unit pixel of a typical 3T type CMOS image sensor;

FIG. 2 is a sectional view taken along line II-II of FIG. 1, illustrating a photodiode and a transfer transistor of a related art CMOS image sensor;

FIG. 3 is a sectional view taken along line II-II of FIG. 1, illustrating a photodiode and a transfer transistor of a CMOS image sensor according to the present invention; and

FIG. 4A to FIG. 4F are sectional views illustrating a method for fabricating a CMOS image sensor according to an embodiment of the present invention.

### DETAILED DESCRIPTION OF THE INVENTION

Reference will now be made in detail to exemplary embodiments of the present invention, examples of which are illustrated in the accompanying drawings. Wherever possible, the same reference numbers will be used throughout the drawings to refer to the same or like parts.

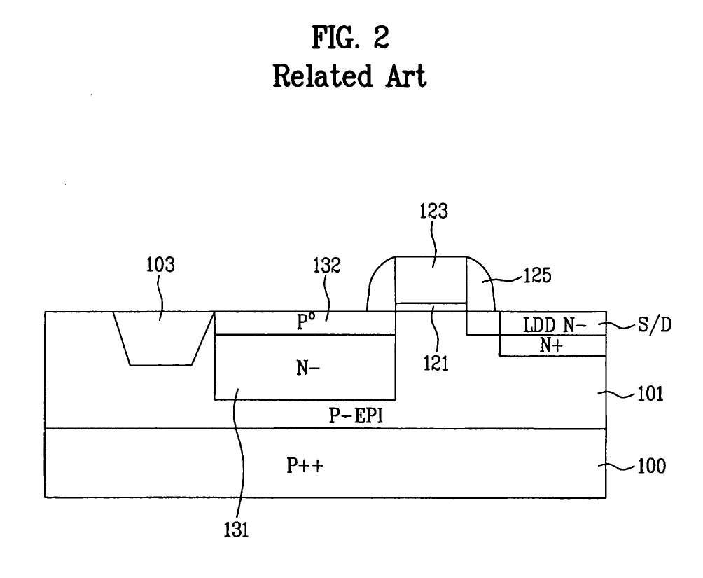

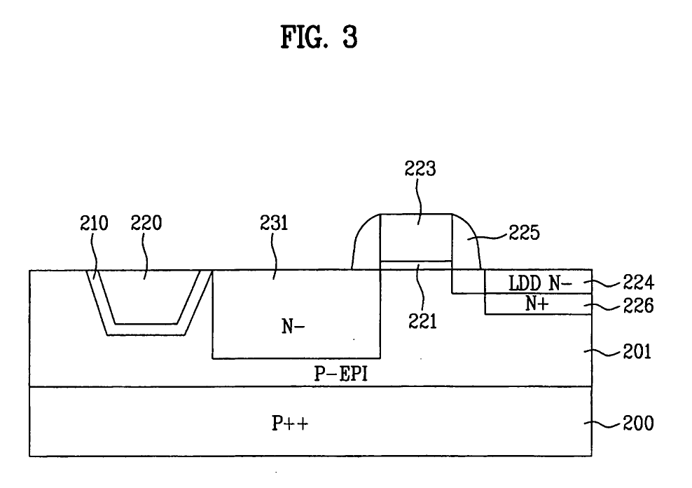

FIG. 3 is a sectional view analogous to the view of FIG. 2, illustrating a photodiode and a transfer transistor of a CMOS image sensor according to the present invention.

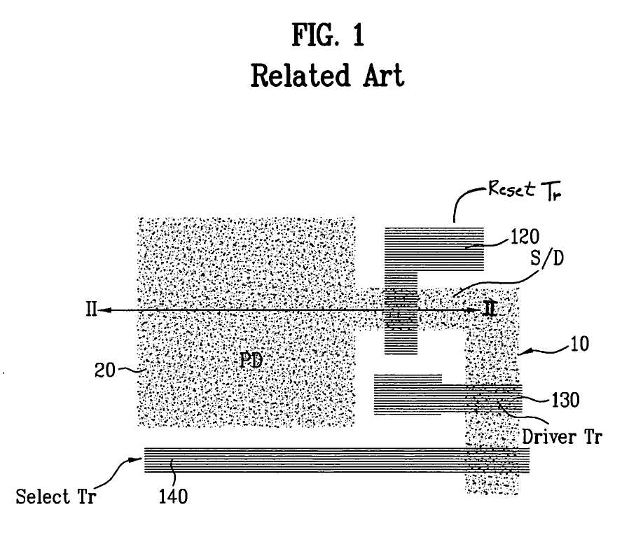

As shown in FIG. 3, a P⁻ type epitaxial layer 201 is formed on a p⁺⁺ type semiconductor substrate 200 defined by an active region 10 (see FIG. 1) and a device isolation region. A device isolation film 220, i.e., a shallow trench isolation (STI) film, is formed in the device isolation region over the semiconductor substrate 200.

The active region of the semiconductor substrate 200 is defined by a photodiode region PD and a transistor region.

A gate 223 is formed on a portion of an epitaxial layer 201 for a transfer transistor 120 of FIG. 1 by interposing a gate insulating film 221. An insulating spacer 225 is formed on both sides of gate 223.

An n⁻ type diffusion region 231 is formed in the epitaxial layer 201 of the photodiode region PD.

Furthermore, source and drain regions S/D are formed in a surface of the epitaxial layer 201 at one side of the gate 223. The source and drain regions S/D are formed with a heavily doped n type diffusion region (n⁺) 226 and a lightly doped n type diffusion region (n⁻) 224.

Meanwhile, a P⁺ type epitaxial layer 210 is formed on a boundary of the device isolation film 220 to prevent a dark current from being generated by adjoining the device isolation film 220 to the n⁻ type diffusion region 231 corresponding to the photodiode region.

When the photodiode region is formed with the P⁺ type epitaxial layer 210 formed at one side of the device isolation film 220, the n⁻ type ions are prevented from being implanted into the boundary of the device isolation film 220 so as not to adjoin the n⁻ type diffusion region 231 to the device isolation film 220.

The P⁺ type epitaxial layer 210 may have a thickness of 100 Å to 500 Å.

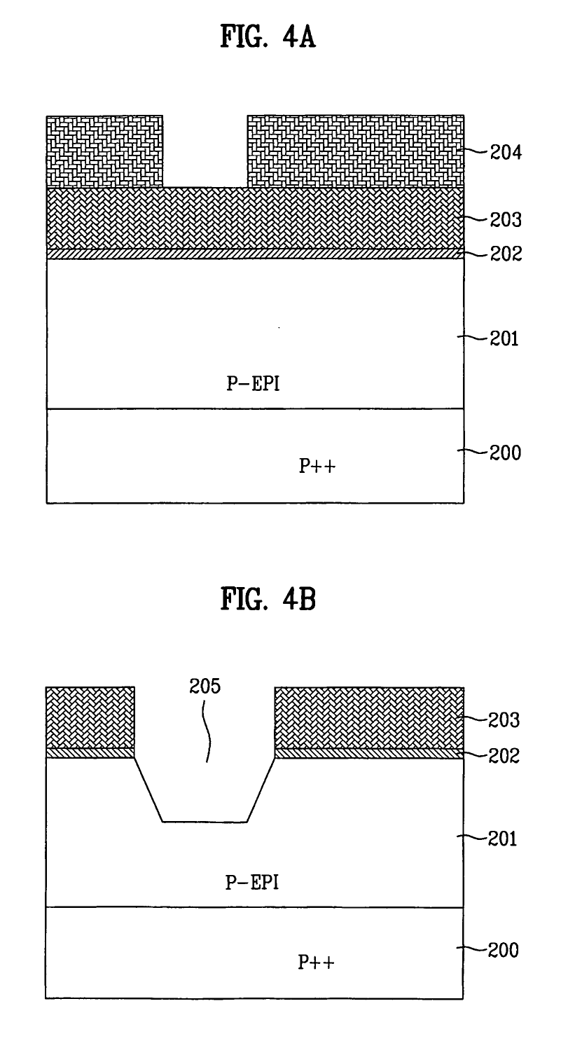

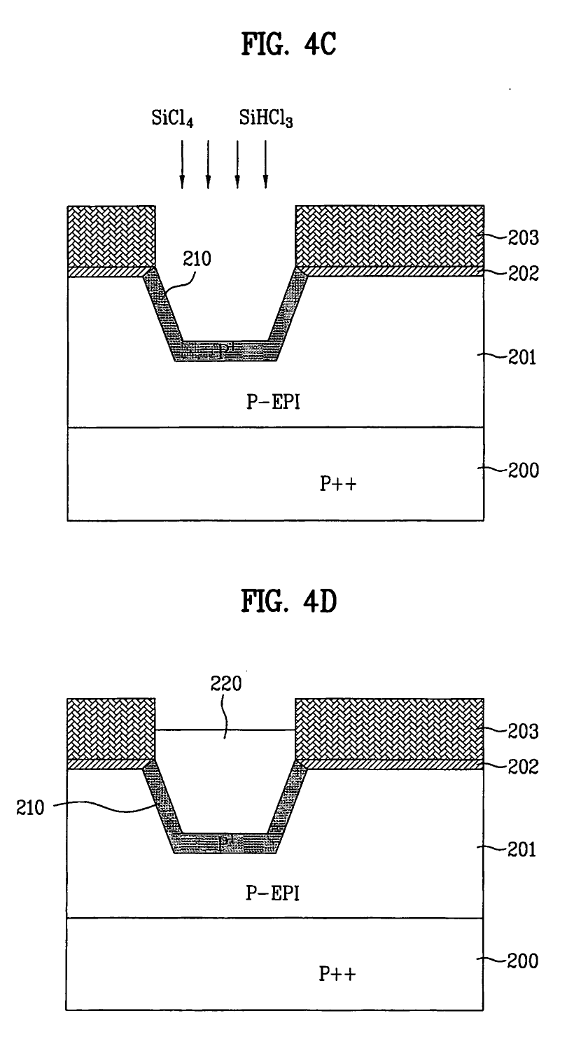

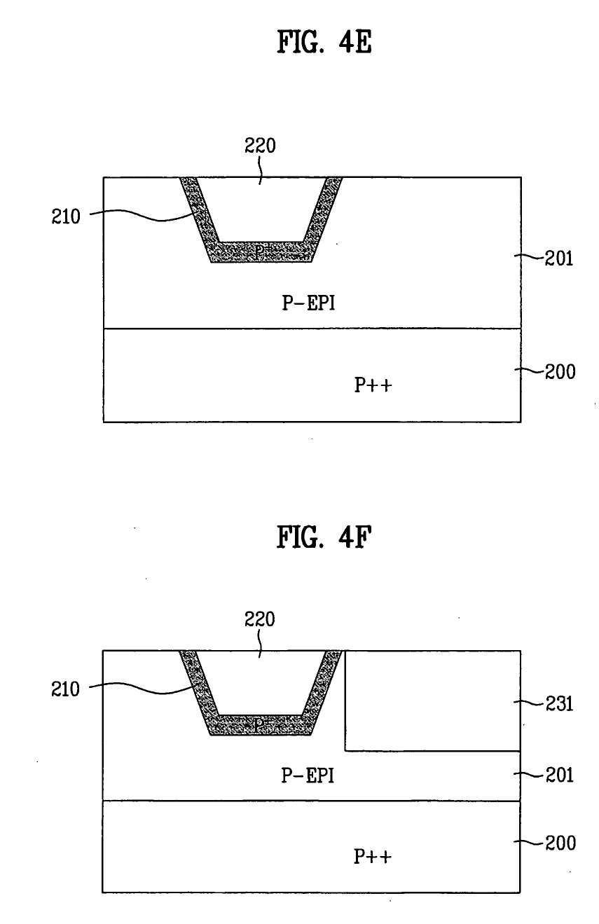

FIG. 4A to FIG. 4F are sectional views illustrating a method for fabricating the CMOS image sensor according to an embodiment of the present invention.

The method for fabricating the CMOS image sensor according to an embodiment of the present invention will be described based on a method for forming the device isolation film and the photodiode region in the semiconductor device defined by the device isolation region and the active region.

As shown in FIG. 4A, a first conductivity type (P⁻ type) lightly doped epitaxial layer 201 is formed on a semiconductor substrate 200 of a first conductivity type (P⁺⁺ type) heavily doped monosilicon by an epitaxial process.

The epitaxial layer 201 is to improve capability of a low voltage photodiode for converging optical charges and photosensitivity by greatly and deeply forming a depletion region in the photodiode.

Subsequently, an oxide film 202 is formed over the semiconductor substrate 200 including the epitaxial layer 201, and a nitride film 203 is formed on the oxide film 202.

A photoresist 204 is then deposited on the nitride film 203 and patterned by an exposing and developing process to define the device isolation region.

The nitride film 203 and the oxide film 202 are selectively etched by an etching process using the patterned photoresist 204 as a mask, so as to expose the surface of the epitaxial layer 201.

The exposed portion of the epitaxial layer 201 corresponds to the device isolation region.

As shown in FIG. 4B, the exposed epitaxial layer 201 is selectively etched using the patterned photoresist 204 as a mask to form a trench 205 having a predetermined depth.

Subsequently, the photoresist 204 used to form the trench 205 is removed.

As shown in FIG. 4C, the P⁺ type epitaxial layer 210 is formed on the surface of the trench 205 by implanting P⁺ ions into the exposed trench 205 using the nitride film 203 and the oxide film 202 as masks. In one embodiment of the present invention the P⁺ type epitaxial layer 210 is formed by implanting halogen ions that increase the surface movement of silicon atoms and thus form the P⁺ type epitaxial layer 210 only on the exposed trench 205. SiHCl₃ or SiCl₄ may be used as the halogen ion.

B or BF₂ may also be implanted into the exposed trench 205 as a source gas along with the halogen ion to induce recombination of electrons.

The P⁺ type epitaxial layer 210 is formed on the surface of the exposed epitaxial layer 201 by increasing surface mobility of silicon atoms using the halogen ion such as SiHCl₃ or SiCl₄.

The P⁺ type epitaxial layer 210 may also be formed by ion implantation of B or Ga.

Furthermore, the P⁺ type epitaxial layer 210 may be formed of a thickness of 100 Å to 500 Å.

As shown in FIG. 4D, an insulating film such as spin on glass (SOG) or undoped silicate glass (USG) is deposited on the entire surface of the device including the trench 205.

Subsequently, a chemical mechanical polishing (CMP) process or an etch-back process is performed on the entire surface of the semiconductor substrate so that the device isolation film 220 remains in the trench 205.

As shown in FIG. 4E, the nitride film 203 and the oxide film 202 are removed and cleaning and planarizing processes are performed to form the device isolation film 220 buried in the trench 205.

As shown in FIG. 4F, a photoresist (not shown) is deposited over the semiconductor substrate 200 and then patterned by exposing and developing processes to expose the photodiode region. Using the patterned photoresist as a mask n⁻ type impurity ions are implanted into the epitaxial layer 201 to form the n⁻ type diffusion region 231 in the photodiode region. In this manner, the P⁺ type epitaxial layer 210 creates a constant interval between the device isolation film 220 and the n-type diffusion region 231.

Although not shown, a gate is formed in the active region of the device by interposing a gate insulating film before the n⁻ type diffusion region 231 is formed.

During the formation of the n⁻ type diffusion region 231 the P⁺ type epitaxial layer 210 is between the n⁻ type diffusion region 231 being formed and the device isolation film 220. In this manner, the P⁺ type epitaxial layer 210 serves to reduce the dark current generated in the boundary portion between the photodiode region and the device isolation film 220.

Additionally, a P^{o} type diffusion region (not shown) may further be formed on the n⁻ type diffusion region 231.

As described above, the CMOS image sensor and the method for fabricating the same according to the present invention have the many advantages.

For example, by forming the P⁺ type epitaxial layer in the boundary portion between the photodiode region and the device isolation film, it is possible to prevent defects from occurring.

Additionally, since the P⁺ type epitaxial layer is formed in the boundary portion between the photodiode region and the device isolation film, it is possible to minimize the dark current that may be generated in the boundary portion between the photodiode region and the device isolation film, thereby improving operational reliability of the CMOS image sensor.

Furthermore, since the P⁺ type epitaxial layer is selectively formed in the boundary of the device isolation film, it is possible to reduce the dark current of the image sensor by inducing recombination of the electrons generated in the boundary of the device isolation film.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A CMOS image sensor comprising:
a first conductivity type semiconductor substrate defined by an active region and a device isolation region;
a device isolation film formed in the device isolation region;
a second conductivity type lightly doped diffusion region formed in the active region; and
a first conductivity type heavily doped epitaxial layer formed in the periphery of the device isolation film including a boundary portion between the device isolation film and the second conductivity type lightly doped diffusion region.

2. The CMOS image sensor according to claim 1, wherein the device isolation film is a shallow trench isolation (STI) film.

3. The CMOS image sensor according to claim 1, wherein the first conductivity type heavily doped epitaxial layer has a thickness of 100 Å to 500 Å.

4. The CMOS image sensor according to claim 1, wherein a first conductivity type lightly doped epitaxial layer is formed over the first conductivity type semiconductor substrate.

5. A method for fabricating a CMOS image sensor comprising:
forming a trench in a device isolation region of a first conductivity type semiconductor substrate defined by an active region and the device isolation region;
forming a first conductivity type heavily doped epitaxial layer on a surface of the trench;
forming a device isolation film in the trench; and
forming a second conductivity type diffusion region in the active region of the semiconductor substrate to have a constant interval from the device isolation film via the first conductivity type heavily doped epitaxial layer.

6. The method according to claim 5, wherein forming the trench comprises:
sequentially forming an oxide film and a nitride film over the first conductivity type semiconductor substrate;
selectively etching the nitride film and the oxide film to expose the device isolation region; and
forming the trench on a surface of the exposed device isolation region.

7. The method according to claim 6, further comprising removing the nitride film and the oxide film after forming the device isolation film in the trench.

8. The method according to claim 5, wherein the first conductivity type heavily doped epitaxial layer has a thickness of 100 Å to 500 Å.

9. The method according to claim 5, wherein the first conductive type heavily doped epitaxial layer is formed by implanting halogen ions into the trench.

10. The method according to claim 9, wherein the halogen ions are SiHCl₃ or SiCl₄.

11. The method according to claim 9, wherein the halogen ions are implanted into the trench along with B or BF₂ as a source gas.

12. The method according to claim 5, wherein the first conductivity type heavily doped epitaxial layer is formed by implanting B or Ga into the trench.
